(19) United States
(12) Patent Application Publication
(10) Pub. No.: US 2025/0280656 A1
(43) Pub. Date: Sep. 4, 2025

(54) CHARGE GENERATION LAYER AND STACKED ORGANIC LIGHT-EMITTING DEVICE

(71) Applicant: Yungu (Gu’an) Technology Co., Ltd., Langfang (CN)

(72) Inventors: Mengzhen LI, Langfang (CN); Bin LIU, Langfang (CN); Wei ZHAO, Langfang (CN); Hui PANG, Langfang (CN); Zhenzhen LI, Langfang (CN); Jun LIU, Langfang (CN); Baoyu LI, Langfang (CN)

(73) Assignee: Yungu (Gu’an) Technology Co., Ltd., Langfang (CN)

(21) Appl. No.: 19/214,015

(22) Filed: May 20, 2025

Related U.S. Application Data
(63) Continuation of application No. PCT/CN2023/077235, filed on Feb. 20, 2023.

(30) Foreign Application Priority Data
Nov. 28, 2022 (CN) 202211502354.7

(51) Int. Cl. H10K 50/19; H10K 50/14

(52) U.S. Cl. CPC H10K 50/19; H10K 50/14

(57) ABSTRACT

Embodiments of the present application provide a charge generation layer and a stacked organic light-emitting device. The charge generation layer includes a first charge layer and a second charge layer arranged in a stacked manner, one of the first charge layer and the second charge layer being doped with a P-type dopant and the other being doped with an N-type dopant, wherein in a direction from the first charge layer to the second charge layer, a dopant concentration in at least a portion of the first charge layer has an increasing trend, and a dopant concentration in at least a portion of the second charge layer has a decreasing trend. The present application can alleviate the problem of reduced stability of a first light-emitting device layer and a second light-emitting device layer due to the instability of the charge generation layer.

### CROSS-REFERENCE TO RELATED APPLICATIONS

This application is a continuation application of International Application No. PCT/CN2023/077235, filed on Feb. 20, 2023, which claims priority to Chinese Patent Application No. 202211502354.7, entitled “CHARGE GENERATION LAYER AND STACKED ORGANIC LIGHT-EMITTING DEVICE” and filed on Nov. 28, 2022, which is incorporated herein by reference in its entirety.

### FIELD

The present application relates to the field of display equipment, and in particular to a charge generation layer and a stacked organic light-emitting device.

### BACKGROUND

An organic light-emitting diode (OLED) is an active light-emitting device. Compared with a conventional liquid crystal display (LCD) method, OLED display technology does not require a backlight and has a self-luminescence characteristic. The OLED uses a thin film layer of an organic material and a glass substrate. When a current passes through the film layer of the organic material, the organic material emits light. Therefore, an OLED display panel can significantly save power, and can be made lighter and thinner and withstand a wider range of temperature changes than an LCD panel, and has a larger viewing angle. The OLED display panel is expected to become the next generation of flat panel display technology after LCD and is currently one of the flat panel display technologies that have attracted the most attention.

In the related art, in order to prolong the service life of an OLED display panel, a plurality of OLED devices are stacked and connected in series by a charge generation layer, in which different kinds of metal need to be doped, As the service time increases, metal diffusion can lead to the problem of reduced stability of the OLED devices.

### SUMMARY

Embodiments of the present application provide a charge generation layer and a stacked organic light-emitting device, aimed at solving the problem of reduced device stability of a multi-layer light-emitting device.

Embodiments of a first aspect of the present application provide a charge generation layer, comprising a first charge layer and a second charge layer arranged in a stacked manner, one of the first charge layer and the second charge layer being doped with a P-type dopant and the other being doped with an N-type dopant, wherein in a direction from the first charge layer to the second charge layer, a dopant concentration in at least a portion of the first charge layer has an increasing trend, and a dopant concentration in at least a portion of the second charge layer has a decreasing trend.

Embodiments of a second aspect of the present application also provide a stacked organic light-emitting device, comprising a first light-emitting device layer, a second light-emitting device layer and a charge generation layer of any one of the above embodiments that are arranged in a stacked manner, wherein the first light-emitting device layer and the second light-emitting device layer are connected in series by the charge generation layer.

In the charge generation layer provided in the embodiments of the present application, the charge generation layer comprises a first charge layer and a second charge layer, one of the first charge layer and the second charge layer being doped with a P-type dopant and the other being doped with an N-type dopant, enabling the charge generation layer to generate corresponding charge carriers. In the direction from the first charge layer to the second charge layer, the dopant concentration in at least a portion of the first charge layer has an increasing trend, and the dopant concentration in at least a portion of the second charge layer has a decreasing trend, i.e., the dopant concentrations in at least a portion of the first charge layer and at least a portion of the second charge layer have different variation trends. While a sufficient electron supply is ensured, the ability of an interface to withstand electron bombardment is enhanced, thereby alleviating the problem of reduced device stability of the first light-emitting device layer and the second light-emitting device layer caused by the instability of the charge generation layer, and prolonging the service life of the stacked organic light-emitting device.

### BRIEF DESCRIPTION OF THE DRAWINGS

FIG. 1 is a structural schematic diagram of a stacked organic light-emitting device according to an embodiment of the present application;

FIG. 2 is an energy diagram of a layer structure of a stacked organic light-emitting device according to an embodiment of the present application;

FIGS. 3 to 10 are trend graphs of the variations in dopant concentrations in a first charge layer and a second charge layer of a charge generation layer according to various embodiments of the present application;

FIG. 11 is a structural schematic diagram of a stacked organic light-emitting device according to another embodiment of the present application;

FIGS. 12 to 19 are trend graphs of the variations in dopant concentrations in a first charge layer and a second charge layer of a charge generation layer according to some other various embodiments of the present application; and

FIG. 20 is a schematic flowchart of a preparation method for a stacked organic light-emitting device according to an embodiment of the present application.

### DETAILED DESCRIPTION OF THE EMBODIMENTS

In the description of the present application, it should be noted that “a plurality of” means two or more, unless otherwise specified. The orientation or position relationship indicated by the terms “upper”, “lower”, “left”, “right”, “inner”, “outer”, etc. is only for the convenience of describing the present application and simplifying the description, rather than indicating or implying that the device or element referred to must have a particular orientation or be constructed and operated in a particular orientation, and therefore should not be construed as a limitation on the present application. Moreover, the terms such as “first” and “second” are merely used for illustrative purposes, and should not be construed as indicating or implying relative importance.

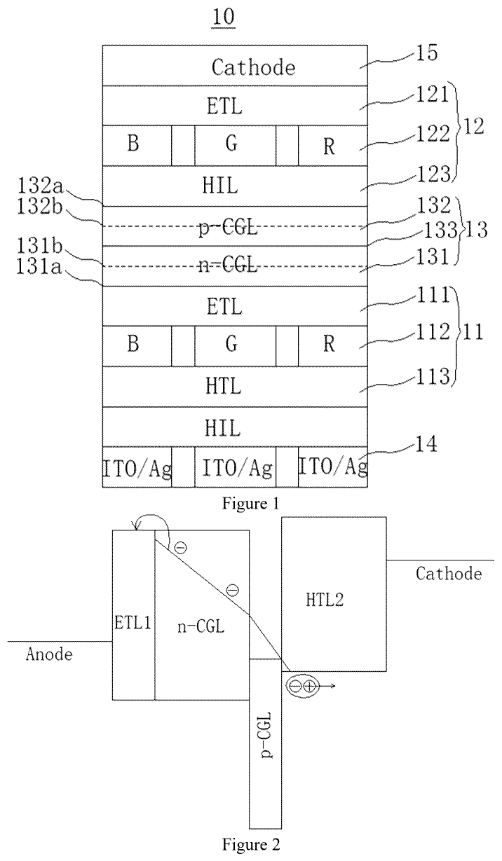

As shown in FIGS. 1, 2 and 11, a stacked organic light-emitting device 10 provided in the present application includes a first light-emitting device layer 11, a second light-emitting device layer 12, and a charge generation layer 13 located between the first light-emitting device layer 11 and the second light-emitting device layer 12, which are stacked in a thickness direction thereof.

In the embodiment provided by the present application, the stacked organic light-emitting device 10 includes the first light-emitting device layer 11 and the second light-emitting device layer 12 arranged in a stacked manner, where both the first light-emitting device layer 11 and the second light-emitting device layer 12 can emit light to achieve display of the stacked organic light-emitting device 10. By providing the first light-emitting device layer 11 and the second light-emitting device layer 12 arranged in a stacked manner, the service life and luminous efficiency of the stacked organic light-emitting device 10 can be improved. The charge generation layer 13 is arranged between the first light-emitting device layer 11 and the second light-emitting device layer 12, and the charge generation layer 13 is used to connect the first light-emitting device layer 11 and the second light-emitting device layer 12.

The charge generation layer 13 may be referred to as an “intermediate connecting layer” because the charge generation layer 13 may control the balance of holes and electrons between the first light-emitting device layer 11 and the second light-emitting device layer 12. The charge generation layer 13 includes a P-type charge generation layer doped with a P-type dopant and an N-type charge generation layer doped with an N-type dopant. The P-type charge generation layer may help to inject holes into one of the first light-emitting device layer 11 and the second light-emitting device layer 12, and the N-type charge generation layer may assist in injecting electrons into the other of the first light-emitting device layer 11 and the second light-emitting device layer 12.

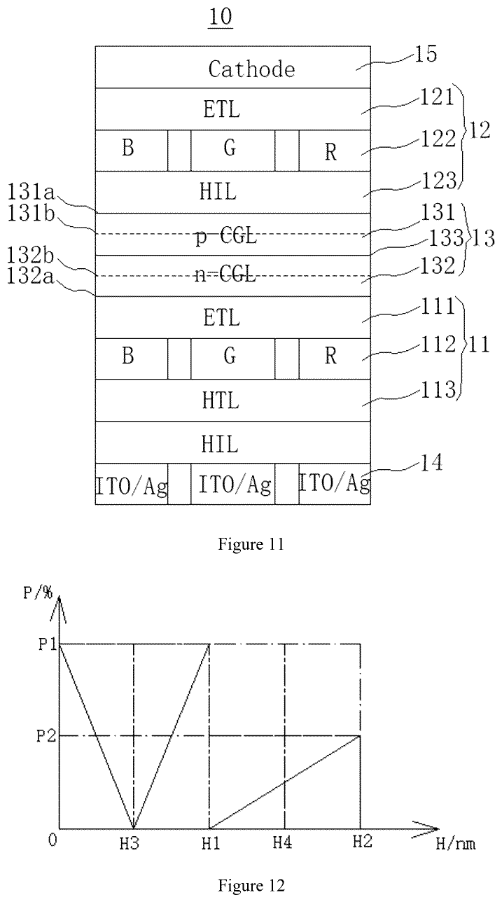

The charge generation layer 13 is configured in a variety of ways, and the embodiment of the present application also provides a charge generation layer, as shown in FIGS. 1 and 11, the charge generation layer 13 includes a first charge layer 131 and a second charge layer 132 arranged in a stacked manner in a thickness direction.

As shown in FIG. 1, the first charge layer 131 is doped with an N-type dopant and the second charge layer 132 is doped with a P-type dopant, wherein in a direction from the first charge layer 131 toward the second charge layer 132, a dopant concentration in at least a portion of the first charge layer 131 has an increasing trend, and a dopant concentration in at least a portion of the second charge layer 132 has a decreasing trend. As shown in FIG. 11, the first charge layer 131 is doped with a P-type dopant and the second charge layer 132 is doped with an N-type dopant. That is, the charge generation layer 13 includes the first charge layer 131 and the second charge layer 132 arranged in a stacked manner, one of the first charge layer 131 and the second charge layer 132 being doped with a P-type dopant and the other being doped with an N-type dopant, wherein in the direction from the first charge layer 131 to the second charge layer 132, the dopant concentration in at least a portion of the first charge layer 131 has an increasing trend, and the dopant concentration in at least a portion of the second charge layer 132 has a decreasing trend.

In the charge generation layer 13 provided in the embodiments of the present application, the charge generation layer 13 includes a first charge layer 131 and a second charge layer 132, one of the first charge layer 131 and the second charge layer 132 being doped with a P-type dopant and the other being doped with an N-type dopant, enabling the charge generation layer 13 to generate corresponding charge carriers. In the direction from the first charge layer 131 to the second charge layer 132, the dopant concentration in at least a portion of the first charge layer 131 has an increasing trend, and the dopant concentration in at least a portion of the second charge layer 132 has a decreasing trend, i.e., the dopant concentrations in at least a portion of the first charge layer 131 and the second charge layer 132 have different variation trends, which can alleviate the problem of reduced device stability of the first light-emitting device layer 11 and the second light-emitting device layer 12 caused by the instability of the charge generation layer 13.

The first light-emitting device layer 11 and the second light-emitting device layer 12 may be OLED light-emitting device layers. In one embodiment, the first light-emitting device layer 11 may include a first electron transport layer 111, a first light-emitting material layer 112 and a first hole transport layer 113, and the second light-emitting device layer 12 may include a second electron transport layer 121, a second light-emitting material layer 122 and a second hole transport layer 123.

In one embodiment, the stacked organic light-emitting device 10 further includes a first electrode 14 and a second electrode 15, the first electrode 14 and the second electrode 15 being arranged on two sides of the first light-emitting device layer 11 and the second light-emitting device layer 12, respectively, one of the first electrode 14 and the second electrode 15 being an anode, the other being a cathode, and the first electrode 14, the second electrode 15 and the charge generation layer 13 together drive the first light-emitting device layer 11 and the second light-emitting device layer 12 to emit light.

In one embodiment, the first light-emitting material layer 112 and the second light-emitting material layer 122 may each include a red light-emitting unit, a green light-emitting unit, and a blue light-emitting unit to achieve colored display of the stacked organic light-emitting device 10.

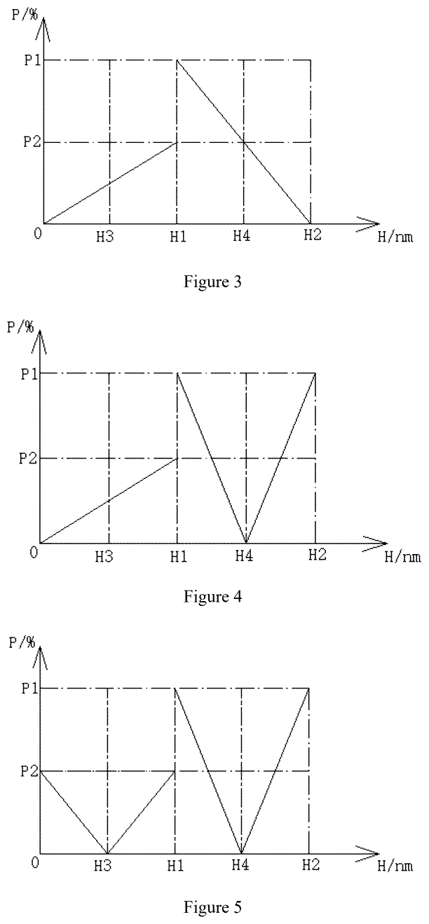

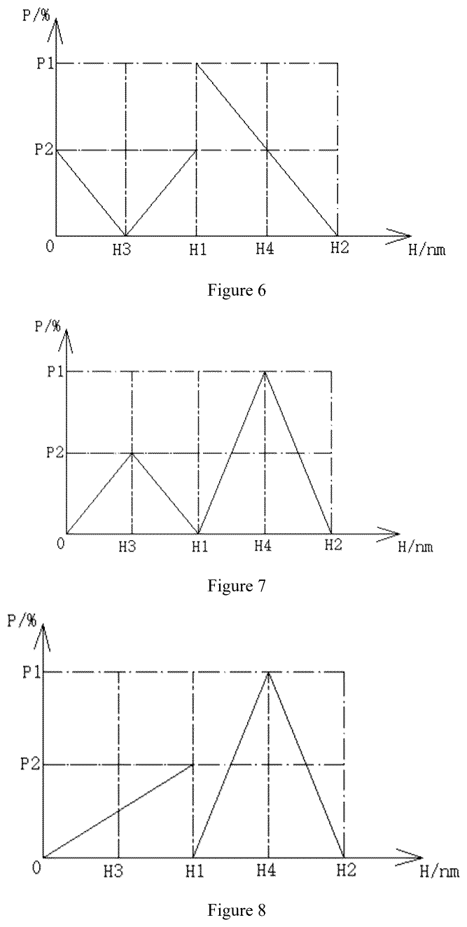

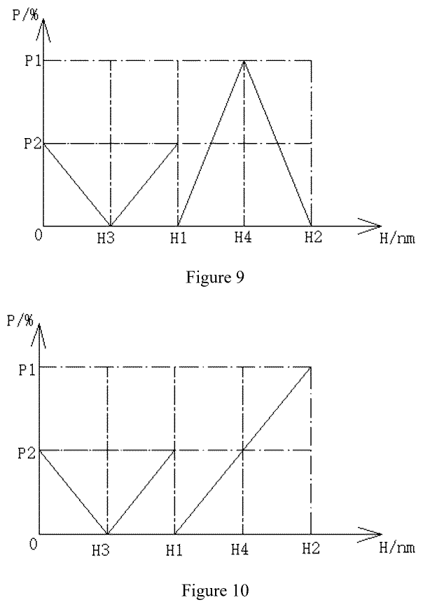

According to the structure of the stacked organic light-emitting device 10 shown in FIG. 1, in the embodiments of FIGS. 3 to 10, in the case of the first charge layer 131 doped with an N-type dopant and the second charge layer 132 doped with a P-type dopant, the graphs of the variation trends of the dopant concentrations in the first charge layer 131 and the second charge layer 132 of the charge generation layer 13 are illustrated in some various embodiments. In the above embodiments, the first charge layer 131 is adjacent to the first electron transport layer 111, and the second charge layer 132 is adjacent to the second hole transport layer 123.

In one embodiment, in the direction from the first charge generation layer 131 to the second charge generation layer 132, the dopant concentration in at least a portion of the first charge layer 131 having an increasing trend includes: In the direction from the first charge generation layer 131 to the second charge generation layer 132, the dopant concentration in the entirety of the first charge layer 131 has an increasing trend; in one embodiment, the dopant concentration in a portion of the first charge layer 131 has an increasing trend, and the dopant concentration in another portion of the first charge layer 131 has a decreasing trend or remains constant. When the dopant of the first charge layer 131 is an N-type dopant, in the direction from the first light-emitting device layer 11 to the second light-emitting device layer 12, the concentration of the N-type dopant in the first charge layer 131 has an increasing trend, or the concentration of the N-type dopant in a portion of the first charge layer 131 has an increasing trend, and the concentration of the N-type dopant in another portion of the first charge layer 131 has a decreasing trend.

In one embodiment, when the dopant of the first charge layer 131 is an N-type dopant, the dopant concentration of the N-type dopant may vary from 0% to 10%. For example, the dopant concentration of the N-type dopant may vary from 1% to 10%. In this application, the dopant concentration of the dopant is a ratio of the volume of the dopant to the total volume.

In one embodiment, in the direction from the first charge layer 131 to the second charge layer 132, the dopant concentration in at least a portion of the second charge layer 132 having a decreasing trend involves that: in the direction from the first charge layer 131 to the second charge layer 132, the dopant concentration in entirety of the second charge layer 132 has a decreasing trend, or the dopant concentration in a portion of the second charge layer 132 has a decreasing trend, and the dopant concentration in another portion of the second charge layer 132 has a decreasing trend or remains constant. When the dopant of the second charge layer 132 is a P-type dopant, in the direction from the first light-emitting device layer 11 to the second light-emitting device layer 12, the concentration of the P-type dopant in the entirety of the second charge layer 132 has a decreasing trend, or the concentration of the P-type dopant in a portion of the second charge layer 132 has a decreasing trend, and the concentration of the P-type dopant in another portion of the second charge layer 132 has an increasing trend.

In one embodiment, when the dopant of the second charge layer 132 is a P-type dopant, the volume ratio of the dopant concentration of the P-type dopant may vary from 0% to 20%. For example, when the dopant of the second charge layer 132 is a P-type dopant, the volume ratio of the dopant concentration of the P-type dopant may vary from 2% to 20%.

In one embodiment, the first charge layer 131 has a thickness in the range from 5 nm to 30 nm. The second charge layer 132 has a thickness in the range from 5 nm to 30 nm.

In one embodiment, the P-type dopant is a kind of material with deep Lowest Unoccupied Molecular Orbital (LUMO) and strong electron-withdrawing properties, and the N-type dopant may be metal such as alkali metal, alkaline earth metal, lanthanide metal and transition metal, and compounds thereof.

In some optional embodiments, in a direction toward a contact interface 133 between the first charge layer 131 and the second charge layer 132, the dopant concentrations in at least a portion of the first charge layer 131 and of the second charge layer 132 both have an increasing trend. That is, the dopant concentration in at least a portion of the first charge layer 131 has an increasing trend in a direction toward the contact interface 133, and the dopant concentration in at least a portion of the second charge layer 132 has an increasing trend in a direction toward the contact interface 133. By way of example, the direction from the first charge layer 131 toward the contact interface 133 and the direction from the second charge layer 132 toward the contact interface 133 are illustrated below. Referring to FIG. 1, the direction from the first charge layer 131 toward the contact interface 133 is the direction from the first charge layer 131 to the second charge layer 132, and the direction from the second charge layer 132 toward the contact interface 133 is the direction from the second charge layer 132 to the first charge layer 131.

As shown in FIG. 1 and FIGS. 3 to 10, with reference to the direction from the first light-emitting device layer 11 to the second light-emitting device layer 12, the dopant of the first charge layer 131 is an N-type dopant, the dopant of the second charge layer 132 is a P-type dopant, a surface of the first light-emitting device layer 11 close to the first charge layer 131 is a first reference surface, and a surface of the second light-emitting device layer 12 close to the second charge layer 132 is a second reference surface. The abscissa in FIGS. 3 to 10 represents a distance H from the first reference surface. The distance from a first interface 131a to the first reference surface is defined to be 0, the distance from the contact interface to the first reference surface is defined as H1, the distance from a second interface 132a to the first reference surface is defined as H2, the distance from a first intermediate interface 131b to the first reference surface is defined as H3, and the distance from a second intermediate interface 132b to the first reference surface is defined as H4. The ordinates in FIGS. 3 to 10 represent the dopant concentration P in the first charge layer 131 and the second charge layer 132, the dopant concentration in the first charge layer 131 varying from 0 to P1, and the dopant concentration in the second charge layer varying from 0 to P2. P1 has a value in the range from 0% to 10%, P2 has a value in the range from 0% to 20%, and neither P1 nor P2 takes the value of 0.

In the embodiments of the present application, in the case of both the thickness of the first charge layer 131 and the thickness of the second charge layer 132 being 15 nm, that is, H1 is 15 nm, H2 is 30 nm, H3 takes the value of 7.5 nm and H4 takes the value of 22.5 nm. The dopant concentration in the first charge layer 131 varies gradually between 0% and 10%. The dopant concentration in the second charge layer 132 varies between 0% and 20%, i.e., 10% for P1 and 20% for H2.

As can be seen from FIGS. 3 to 6, the dopant concentrations in at least a portion of the first charge layer 131 and the second charge layer 132 have an increasing trend in the direction toward the contact interface 133.

In these optional embodiments, the dopant concentrations in at least a portion of the first charge layer 131 and the second charge layer 132 both have an increasing trend in the direction toward the contact interface 133. That is, in the vicinity of the contact interface 133, the dopant concentrations in the first charge layer 131 and the second charge layer 132 are both relatively large, which can reduce a charge barrier between the first charge layer 131 and the second charge layer 132, and charge carriers can be transported between the first charge layer 131 and the second charge layer 132 at a smaller voltage, i.e., the first light-emitting device layer 11 and the second light-emitting device layer 12 can be illuminated even with a smaller voltage. Thus, the power consumption of the stacked organic light-emitting device 10 can be reduced. In one embodiment, in the above embodiments, the first charge layer 131 and the second charge layer 132 have the highest dopant concentrations at the contact interface 133, thereby further reducing the power consumption of the stacked organic light-emitting device 10.

In some optional embodiments, as shown in FIGS. 1, 3 and 4, the first charge layer 131 has a first interface 131a on the side facing away from the second charge layer 132, and the dopant concentration in the first charge layer 131 has an increasing trend in the direction from the first interface 131a to the contact interface 133. That is, the overall dopant concentration in the first charge layer 131 increases in the direction toward the contact interface 133, the doping complexity of the first charge layer 131 can be simplified, thereby facilitating the preparation and molding of the first charge layer 131, and improving the preparation efficiency of the stacked organic light-emitting device 10.

In some optional embodiments, as shown in FIGS. 1, 5, and 6, the first charge layer 131 has the first interface 131a on the side facing away from the second charge layer 132, and the first intermediate interface 131b located between the first interface 131a and the contact interface 133, and the dopant concentration in the first charge layer 131 has an increasing trend in the direction from the first intermediate interface 131b to the contact interface 133.

In these optional embodiments, in the vicinity of the contact interface 133, the dopant concentration in the first charge layer 131 is relatively high, which can reduce the charge barrier between the first charge layer 131 and the second charge layer 132, thereby reducing the power consumption of the stacked organic light-emitting device 10.

In one embodiment, the dopant concentration in the first charge layer 131 has an increasing trend in the direction from the first intermediate interface 131b to the first interface 131a. That is, in the vicinity of the first interface 131a, the dopant concentration in the first charge layer 131 is relatively low.

In some optional embodiments, as shown in FIGS. 1, 3, and 6, the second charge layer 132 has a second interface 132a on the side facing away from the first charge layer 131, and the dopant concentration in the second charge layer 132 has an increasing trend in the direction from the second interface 132a to the contact interface 133. That is, the overall dopant concentration in the second charge layer 132 decreases in the direction toward the contact interface 133, which can simplify the doping complexity of the second charge layer 132 to facilitate the preparation and molding of the second charge layer 132 and enable improved preparation efficiency of the stacked organic light-emitting device 10.

In some optional embodiments, as shown in FIGS. 1, 4, and 5, the second charge layer 132 has a second interface 132a on the side facing away from the first charge layer 131, and a second intermediate interface 132b located between the second interface 132a and the contact interface 133, and the dopant concentration in the second charge layer 132 has an increasing trend in the direction from the second intermediate interface 132b to the contact interface 133.

In these optional embodiments, in the vicinity of the contact interface 133, the dopant concentration in the second charge layer 132 is relatively large, which can reduce the charge barrier between the first charge layer 131 and the second charge layer 132, and reduce the power consumption of the stacked organic light-emitting device 10.

In one embodiment, the dopant concentration in the second charge layer 132 has an increasing trend in the direction from the second intermediate interface 132b to the second interface 132a. That is, in the vicinity of the second interface 132a, the dopant concentration in the second charge layer 132 is relatively low, which can reduce the charge barrier between the second charge layer 132 and the second light-emitting device layer 12, and reduce the power consumption of the stacked organic light-emitting device 10.

In some optional embodiments, as shown in FIGS. 1 and 7, the dopant concentration in a portion of the first charge layer 131 has a decreasing trend in the direction toward the contact interface 133 between the first charge layer 131 and the second charge layer 132, the dopant concentration in another portion of the first charge layer 131 has an increasing trend, the dopant concentration in the second charge layer 132 has a decreasing trend, and the dopant concentration in another portion of the second charge layer 132 has an increasing trend. That is, the dopant concentration in a portion of the first charge layer 131 has an increasing trend in the direction toward the contact interface 133, and the dopant concentration in another portion of the first charge layer 131 has a decreasing trend in the direction toward the contact interface 133, the dopant concentration in a portion of the second charge layer 132 has a decreasing trend in the direction toward the contact interface 133, and the dopant concentration in another portion of the first charge layer 132 has an increasing trend in the direction toward the contact interface 133.

In these optional embodiments, in the direction toward the contact interface 133, the dopant concentrations in at least a portion of the first charge layer 131 and the second charge layer 132 both decrease. Reasonably setting the dopant concentrations in the first charge layer 131 and the second charge layer 132 can ensure that the barrier between the first charge layer 131 and the second charge layer 132 is relatively low and that the barrier between the first charge layer 131 and the first light-emitting device layer 11, and the barrier between the second charge layer 132 and the second light-emitting device layer are relatively low, thereby reducing the power consumption of the stacked organic light-emitting device 10.

In one embodiment, as described above, as shown in FIGS. 1 and 7, the first charge layer 131 has a first interface 131a and a first intermediate interface 131b, and the dopant concentration in the first charge layer 131 has a decreasing trend in the direction from the first intermediate interface 131b to the contact interface 133 or the first interface 131a.

In these optional embodiments, in the vicinity of the first intermediate interface 131b, the dopant concentration in the first charge layer 131 is relatively low, and in the direction from the first intermediate interface 131b to the contact interface 133 or the first interface 131a, the dopant concentration in the first charge layer 131 increases, which can alleviate the problem of reduced device stability of the first light-emitting device layer 11 and the second light-emitting device layer 12 caused by the instability of the charge generation layer 130.

In one embodiment, as described above, the second charge layer 132 has a second interface 132a and a second intermediate interface 132b, and in a direction from the second intermediate interface 132b to the contact interface 133 or the second interface 132a, as shown in FIGS. 1 and 7, the dopant concentration in the second charge layer 132 has a decreasing trend.

In these optional embodiments, in the vicinity of the second intermediate interface 132b, the dopant concentration in the second charge layer 132 is relatively low, and in the direction from the second intermediate interface 132b to the contact interface 133 or the second interface 132a, the dopant concentration in the second charge layer 132 increases, which can alleviate the problem of reduced device stability of the first light-emitting device layer 11 and the second light-emitting device layer 12 caused by metal diffusion.

In some optional embodiments, as shown in FIGS. 1, and 8 to 10, in the direction toward the contact interface 133 between the first charge layer 131 and the second charge layer 132, the dopant concentration in at least a portion of one of the first charge layer 131 and the second charge layer 132 has an increasing trend, and the dopant concentration in at least a portion of the other of the first charge layer and the second charge layer has a decreasing trend. That is, the dopant concentration in at least a portion of one of the first charge layer 131 and the second charge layer 132 has an increasing trend in the direction toward the contact interface 133, and the dopant concentration in at least a portion of the other has a decreasing trend in the direction toward the contact interface 133.

In these optional embodiments, in the direction toward the contact interface 133, the dopant concentrations in the first charge layer 131 and the second charge layer 132 has different variation trends such that one of the first charge layer 131 and the second charge layer 132 has a higher dopant concentration in the vicinity of the contact interface 133, and the other has a lower dopant concentration, which can alleviate the problem of reduced device stability of the first light-emitting device layer 11 and the second light-emitting device layer 12 caused by the instability of the charge generation layer 130.

In one embodiment, as shown in FIGS. 1, 8 and 9, in the direction toward the contact interface 133, the dopant concentration in at least a portion of the first charge layer 131 has an increasing trend; the second charge layer 132 has a second interface 132a facing away from the first charge layer 131 and a second intermediate interface 132b located between the contact interface 133 and the second interface 132a, and in the direction from the second intermediate interface 132b to the contact interface 133 or the second interface 132a, the dopant concentration in the second charge layer 132 has a decreasing trend.

In these embodiments, in the direction toward the contact interface 133, the dopant concentration in the first charge layer 131 may have an overall increasing trend, or the dopant concentration in a portion of the first charge layer 131 may have an increasing trend. In the direction from the second intermediate interface 132b to the contact interface 133 or the second interface 132a, the dopant concentration in the second charge layer 132 has a decreasing trend, that is, the dopant concentration in the second charge layer 132 in the vicinity of the second intermediate interface 132b is relatively high, the dopant concentration in the second charge layer 132 in the vicinity of the second interface 132a and the contact interface 133 is relatively low, which can alleviate the problem of reduced device stability of the first light-emitting device layer 11 and the second light-emitting device layer 12 caused by metal diffusion.

In other optional embodiments, as shown in FIG. 10, the first charge layer 131 has a first interface 131a on the side facing away from the second charge layer 132, and a first intermediate interface 131b located between the first interface 131a and the contact interface 133. The dopant concentration in the first charge layer 131 has a decreasing trend in the direction from the first intermediate interface 131b to the contact interface 133 or the first interface 131a, and the dopant concentration in at least a portion of the second charge layer 132 has an increasing trend in the direction toward the contact interface 133.

In these embodiments, in the direction toward the contact interface 133, the dopant concentration in the second charge layer 132 may have an overall increasing trend, or the dopant concentration in a portion of the second charge layer 132 may have an increasing trend. In the direction from the first intermediate interface 131b to the contact interface 133 or the first interface 131a, the dopant concentration in the second charge layer 132 has a decreasing trend, that is, the dopant concentration in the second charge layer 132 in the vicinity of the first intermediate interface 131b is relatively high, and in the vicinity of the first interface 131a or the contact interface 133, the dopant concentration in the second charge layer 132 is relatively low, which can alleviate the problem of reduced device stability of the first light-emitting device layer 11 and the second light-emitting device layer 12 caused by metal diffusion.

As shown in FIGS. 11 to 19, with reference to the direction from the first light-emitting device layer 11 to the second light-emitting device layer 12, the dopant of the first charge layer 131 is a P-type dopant and the dopant of the second charge layer 132 is an N-type dopant, a surface of the first light-emitting device layer 11 close to the first charge layer 131 is a first reference surface, and a surface of the second light-emitting device layer 12 close to the second charge layer 132 is a second reference surface. The abscissa in FIGS. 11 to 19 represents a distance H from the first reference surface. The distance from a first interface 131a to the first reference surface is defined to be 0, the distance from the contact interface 133 to the first reference surface is defined as H1, the distance from a second interface 132a to the first reference surface is defined as H2, the distance from a first intermediate interface 131b to the first reference surface is defined as H3, and the distance from a second intermediate interface 132b to the first reference surface is defined as H4. The ordinates in FIGS. 11 to 19 represent the dopant concentration P in the first charge layer 131 and the second charge layer 132, the dopant concentration in the first charge layer 131 varying from 0 to P1, and the dopant concentration in the second charge layer varying from 0 to P2. P1 has a value in the range from 0% to 20%, P2 has a value in the range from 0% to 10%, and neither P1 nor P2 takes the value of 0.

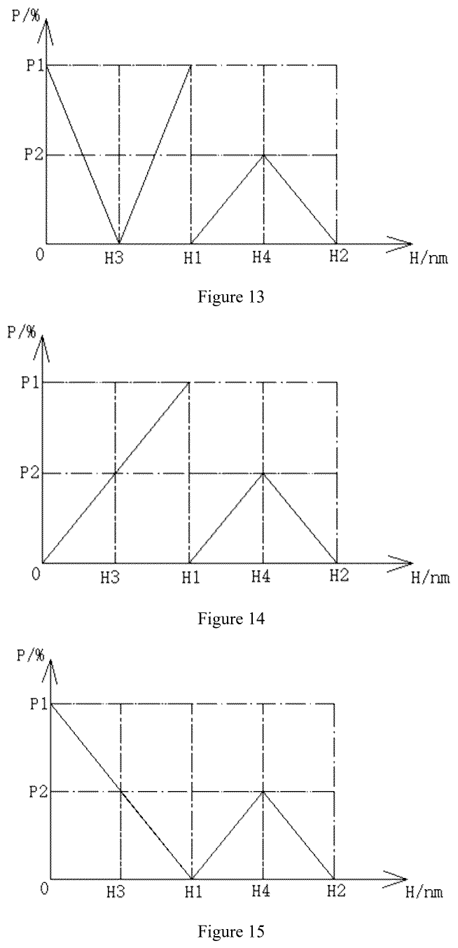

As shown in FIG. 12, the dopant concentration in at least a portion of one of the first charge layer 131 and the second charge layer 132 having an increasing trend in the direction toward the contact interface 133 between the first charge layer 131 and the second charge layer 132 and the dopant concentration in at least a portion of the other having a decreasing trend further involve that: as shown in FIG. 12, the dopant concentration in the first charge layer 131 increases in the direction from the first intermediate interface 131b to the first interface 131a and/or the contact interface 133; and the dopant concentration in the second charge layer 132 increases in the direction from the contact interface 133 to the second interface 132a. In one embodiment, as shown in FIG. 13, the dopant concentration in the first charge layer 131 increases in the direction from the first intermediate interface 131b to the first interface 131a and/or the contact interface 133; The dopant concentration in the second charge layer 132 decreases in the direction from the second intermediate interface 132b to the contact interface 133 and/or the second interface 132a. In one embodiment, as shown in FIG. 14, the dopant concentration in the first charge layer 131 increases in the direction from the first interface 131a to the contact interface 133; and the dopant concentration in the second charge layer 132 decreases in the direction from the second intermediate interface 132b to the second interface 132a and/or the contact interface 133.

As shown in FIG. 12, when the dopant of the first charge layer 131 is a P-type dopant, the P-type dopant concentration in the first charge layer 131 has an increasing trend in the direction from the first light-emitting device layer 12 to the second light-emitting device layer 12. In one embodiment, a portion of the P-type dopant concentration in the first charge layer 131 has an increasing trend, and another portion of the P-type dopant concentration in the first charge layer 131 decreases or remains constant.

As shown in FIG. 12, when the dopant of the first charge layer 131 is a P-type dopant, the volume ratio of the dopant concentration of the P-type dopant may vary from 0% to 20%. For example, the volume ratio of the dopant concentration of the P-type dopant may vary from 2% to 20%.

As shown in FIG. 12, when the dopant of the second charge layer 132 is an N-type dopant, the N-type dopant concentration in the entirety of the second charge layer 132 has a decreasing trend in the direction from the first light-emitting device layer 12 to the second light-emitting device layer 12. In one embodiment, the N-type dopant concentration in a portion of the second charge layer 132 has a decreasing trend, and the N-type dopant concentration in another portion of the second charge layer 132 increases or remains constant.

As shown in FIG. 12, when the dopant of the second charge layer 132 is an N-type dopant, the volume ratio of the dopant concentration of the N-type dopant may vary from 0% to 10%. For example, when the dopant of the second charge layer 132 is an N-type dopant, the volume ratio of the dopant concentration of the N-type dopant may vary from 1% to 10%.

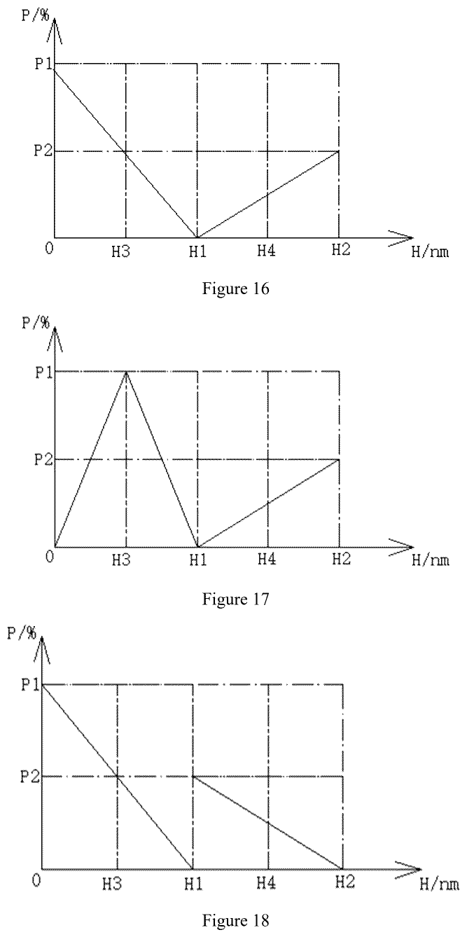

In other embodiments, as shown in FIGS. 11 and 12, when the dopant of the first charge layer 131 is a P-type dopant and the dopant of the second charge layer 132 is an N-type dopant, in the direction toward the contact interface 133 between the first charge layer 131 and the second charge layer 132, the dopant concentration in at least a portion of the first charge layer 131 having a decreasing trend, the dopant concentration in at least another portion of the first charge layer 131 having an increasing trend, the dopant concentration in at least a portion of the second charge layer 132 having a decreasing trend, and the dopant concentration in at least another portion of the second charge layer 132 having an increasing trend further involve that: as shown in FIG. 15, the dopant concentration in the first charge layer 131 decreases in the direction from the first interface 131a to the contact interface 133; and the dopant concentration in the second charge layer 132 decreases in the direction from the second intermediate interface 132b to the contact interface 133 and/or the second interface 132a; in one embodiment, as shown in FIG. 16, the dopant concentration in the first charge layer 131 decreases in the direction from the first interface 131a to the contact interface 133; and the dopant concentration in the second charge layer 132 decreases in the direction from the contact interface 133 to the second interface 132a; in one embodiment, as shown in FIG. 17, the dopant concentration in the first charge layer 131 decreases in the direction from the first intermediate interface 131b to the contact interface 133 and/or the first interface 131a; and the dopant concentration in the second charge layer 132 decreases in the direction from the contact interface 133 to the second interface 132a.

In still other embodiments, as shown in FIGS. 11 and 18, the first charge layer 131 is doped with a P-type dopant and the second charge layer 132 is doped with an N-type dopant, the first light-emitting device layer 11 includes a first hole transport layer 113 located on the side thereof facing the first charge layer 131, and the dopant concentration in at least a portion of the first charge layer 131 has an increasing trend in the direction toward the first hole transport layer 113. That is, the contact interface 133 is provided between the first charge layer 131 and the second charge layer 132, the first charge layer 131 has a first interface 131a on the side facing away from the second charge layer 132, the first interface 131a being configured to be interfaced with a hole transport layer (i.e., the first hole transport layer 113), and in a direction toward the first interface 131a, the dopant concentration in at least a portion of the first charge layer 131 has an increasing trend.

In these optional embodiments, the first charge layer 131 is adjacent to the first hole transport layer 113 by means of the first interface 131a, and the dopant concentration in at least a portion of the first charge layer 131 has an increasing trend in the direction toward the first interface 131a, that is, the P-type dopant concentration in the first charge layer 131 in the vicinity of the first hole transport layer 113 is relatively high, which can reduce the barrier between the first hole transport layer 113 and the first charge layer 131, and reduce the power consumption of the stacked organic light-emitting device 10.

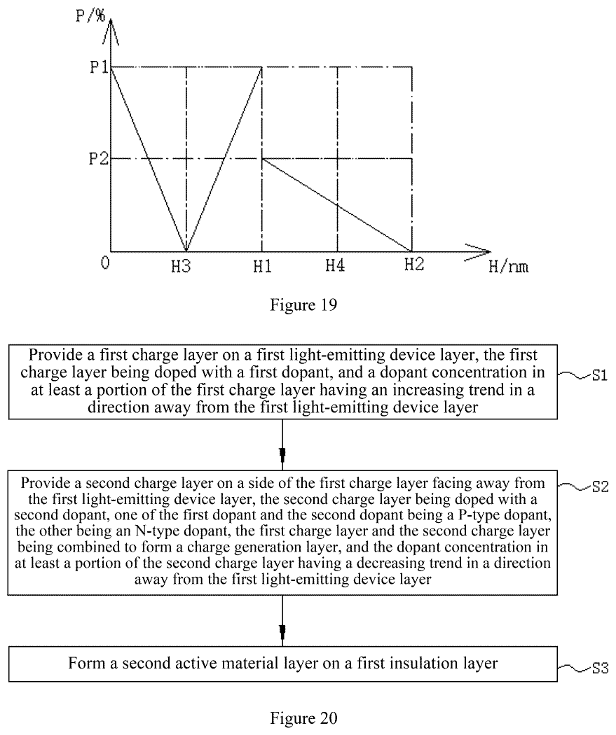

As above, the first charge layer 131 has a first interface 131a and a first intermediate interface 131b. When the first charge layer 131 is doped with a P-type dopant, in one embodiment, as shown in FIGS. 1 and 19, the dopant concentration in the first charge layer 131 has an increasing trend in the direction from the first intermediate interface 131b to the contact interface 133, and the dopant concentration in the first charge layer 131 has an increasing trend in a direction from the first intermediate interface 131b to the first hole transport layer 113.

In these optional embodiments, the dopant concentration in the first charge layer 131 doped with the P-type dopant in the vicinity of the first interface 131a and the contact interface 133 is relatively high, which can reduce the barrier between the first charge layer 131 and the first hole transport layer 113 and reduce the barrier between the first charge layer 131 and the second charge layer 132, thereby better reducing the power consumption of the stacked organic light-emitting device 10.

As above, the second charge layer 132 has a second interface 132a. When the second charge layer 132 is doped with an N-type dopant, in the direction from the second interface 132a to the contact interface 133, the dopant concentration in the second charge layer 132 has an increasing trend. The complexity of the second charge layer 132 can be simplified, and the preparation and molding of the second charge layer 132 are facilitated. The dopant concentration in the second charge layer 132 is relatively high in the vicinity of the contact interface 133, which can reduce the barrier between the first charge layer 131 and the second charge layer 132 and thus the power consumption of the stacked organic light-emitting device 10.

In any one of the above embodiments, when the dopant concentration in the first charge layer 131 has an increasing trend in the direction from the first charge layer 131 to the second charge layer 132, the dopant concentration at the first intermediate interface 131b is an average dopant concentration in the first charge layer 131. This makes the concentration in the first charge layer 131 less susceptible to abrupt changes.

In any of the above embodiments, when the dopant concentration in the second charge layer 132 has a decreasing trend in the direction from the first charge layer 131 to the second charge layer 132, the dopant concentration at the second intermediate interface 132b is an average dopant concentration in the second charge layer 132. This makes the concentration in the second charge layer 132 less susceptible to abrupt changes.

The embodiment of the second aspect of the present application further provides a display device, including the stacked organic light-emitting device 10 according to any one of the above embodiments of the first aspect. Since the display device according to the embodiment of the second aspect of the present application includes the stacked organic light-emitting device 10 according to any one of the above embodiments of the first aspect, the display device according to the embodiment of the second aspect of the present application has the beneficial effects of the stacked organic light-emitting device 10 according to any one of the above embodiments of the first aspect, which will not be repeated here.

The display device in the embodiment of the present application includes, but is not limited to devices having a display function, such as a cell phone, a personal digital assistant (PDA), a tablet computer, an e-book, a television, an access control, a smart fixed-line telephone, or a control console.

As shown in FIG. 20, the embodiment of a third aspect of the present application further provides a preparation method for a stacked organic light-emitting device 10, which may be the stacked organic light-emitting device 10 according to any one of the above embodiments of the first aspect, the method including:
step S01: providing a first charge layer 131 on a first light-emitting device layer 11, wherein the first charge layer 131 is doped with a first dopant, and a dopant concentration in at least a portion of the first charge layer 131 has an increasing trend in a direction away from the first light-emitting device layer 11;
step S02: providing a second charge layer 132 on a side of the first charge layer 131 facing away from the first light-emitting device layer 11, wherein the second charge layer 132 is doped with a second dopant; one of the first dopant and the second dopant is a P-type dopant and the other is an N-type dopant; the first charge layer 131 and the second charge layer 132 are combined to form a charge generation layer 13; and the dopant concentration in at least a portion of the second charge layer 132 has a decreasing trend in a direction away from the first light-emitting device layer 11; and
step S03: providing a second light-emitting device layer 12 on a side of the second charge layer 132 facing away from the first charge layer 131 to form the stacked organic light-emitting device 10.

In the stacked organic light-emitting device 10 prepared by the preparation method provided in the embodiment of the present application, the stacked organic light-emitting device 10 includes the first light-emitting device layer 11 and the second light-emitting device layer 12 arranged in a stacked manner, and the first light-emitting device layer 11 and the second light-emitting device layer 12 can emit light to achieve display of the stacked organic light-emitting device 10. By providing the first light-emitting device layer 11 and the second light-emitting device layer 12 arranged in a stacked manner, the service life and luminous efficiency of the stacked organic light-emitting device 10 can be improved. The charge generation layer 13 is arranged between the first light-emitting device layer 11 and the second light-emitting device layer 12, and the charge generation layer 13 is configured to drive the first light-emitting device layer 11 and the second light-emitting device layer 12 to emit light. The charge generation layer 13 includes the first charge layer 131 and the second charge layer 132. One of the first charge layer 131 and the second charge layer 132 is doped with a P-type dopant and the other is doped with an N-type dopant, enabling the charge generation layer 13 to generate corresponding charge carriers. In the direction from the first light-emitting device layer 11 to the second light-emitting device layer 12, the dopant concentration in at least a portion of the first charge layer 131 has an increasing trend, and the dopant concentration in at least a portion of the second charge layer 132 has a decreasing trend, that is, the dopant concentrations in at least a portion of the first charge layer 131 and the second charge layer 132 has different variation trends, which can alleviate the problem of reduced device stability of the first light-emitting device layer 11 and the second light-emitting device layer 12 caused by metal diffusion.

1. A charge generation layer, comprising:
a first charge layer and a second charge layer arranged in a stacked manner, one of the first charge layer and the second charge layer being doped with a P-type dopant and the other being doped with an N-type dopant,
wherein in a direction from the first charge layer to the second charge layer, a dopant concentration in at least a portion of the first charge layer having an increasing trend, and a dopant concentration in at least a portion of the second charge layer having a decreasing trend.

2. The charge generation layer according to claim 1, wherein a contact interface is present between the first charge layer and the second charge layer, the dopant concentration in at least a portion of the first charge layer has an increasing trend in a direction toward the contact interface, and the dopant concentration in at least a portion of the second charge layer has an increasing trend in a direction toward the contact interface.

3. The charge generation layer according to claim 2, wherein the first charge layer has a first interface on a side facing away from the second charge layer, and the dopant concentration in the first charge layer has an increasing trend in a direction from the first interface to the contact interface;
and the second charge layer has a second interface on a side facing away from the first charge layer, and the dopant concentration in the second charge layer has an increasing trend in a direction from the second interface to the contact interface.

4. The charge generation layer according to claim 2, wherein the first charge layer has a first interface on a side facing away from the second charge layer and a first intermediate interface located between the first interface and the contact interface, the dopant concentration in the first charge layer has an increasing trend in a direction from the first intermediate interface to the contact interface, and the dopant concentration in the first charge layer has an increasing trend in a direction from the first intermediate interface toward the first interface;
and the second charge layer has a second interface on the side facing away from the first charge layer and a second intermediate interface located between the second interface and the contact interface, the dopant concentration in the second charge layer has an increasing trend in a direction from the second intermediate interface to the contact interface, and the dopant concentration in the second charge layer has an increasing trend in a direction from the second intermediate interface to the second interface.

5. The charge generation layer according to claim 1, wherein a contact interface is provided between the first charge layer and the second charge layer, a dopant concentration in a portion of the first charge layer having an increasing trend in a direction toward the contact interface, and a dopant concentration in another portion of the first charge layer having a decreasing trend in a direction toward the contact interface, a dopant concentration in a portion of the second charge layer having a decreasing trend in a direction toward the contact interface, and the dopant concentration in another portion of the first charge layer having an increasing trend in a direction toward the contact interface.

6. The charge generation layer according to claim 5, wherein the first charge layer has a first interface on a side facing away from the second charge layer, and a first intermediate interface located between the first interface and the contact interface, and the dopant concentration in the first charge layer has a decreasing trend in a direction from the first intermediate interface to the contact interface or the first interface;
and the second charge layer has a second interface on a side facing away from the first charge layer, and a second intermediate interface located between the second interface and the contact interface, and in a direction from the second intermediate interface to the contact interface and a direction from the second intermediate interface to the first interface, the dopant concentration in the second charge layer has a decreasing trend.

7. The charge generation layer according to claim 1, wherein a contact interface is present between the first charge layer and the second charge layer, a dopant concentration in at least a portion of one of the first charge layer and the second charge layer having an increasing trend in a direction toward the contact interface, and a dopant concentration in at least a portion of the other of the first charge layer and the second charge layer having a decreasing trend in a direction toward the contact interface.

8. The charge generation layer according to claim 7, wherein the dopant concentration in at least a portion of the first charge layer has an increasing trend in the direction toward the contact interface; the second charge layer has a second interface facing away from the first charge layer, and a second intermediate interface located between the contact interface and the second interface, and in a direction from the second intermediate interface to the contact interface or the second interface, the dopant concentration in the second charge layer has a decreasing trend.

9. The charge generation layer according to claim 7, wherein the first charge layer has a first interface on a side facing away from the second charge layer, and a first intermediate interface located between the first interface and the contact interface, the dopant concentration in the first charge layer has a decreasing trend in a direction from the first intermediate interface to the contact interface or the first interface, and the dopant concentration in at least a portion of the second charge layer has an increasing trend in a direction toward the contact interface.

10. The charge generation layer according to claim 1, wherein the first charge layer is doped with the P-type dopant, the second charge layer is doped with the N-type dopant, and a contact interface is provided between the first charge layer and the second charge layer, the first charge layer having a first interface on a side facing away from the second charge layer, and a dopant concentration in at least a portion of the first charge layer has an increasing trend in a direction toward the first interface.

11. The charge generation layer according to claim 10, wherein the first charge layer has a first intermediate interface located between the first interface and the contact interface, the dopant concentration in the first charge layer has an increasing trend in a direction from the first intermediate interface to the contact interface, and the dopant concentration in the first charge layer has an increasing trend in a direction from the first intermediate interface to the first interface.

12. The charge generation layer according to claim 10, wherein the second charge layer has a second interface on a side facing away from the first charge layer, and the dopant concentration in the second charge layer has an increasing trend in a direction from the second interface toward the contact interface.

13. The charge generation layer according to claim 1, wherein the P-type dopant in the first charge layer has a dopant concentration ranging from 0 to 20%;
and the N-type dopant in the second charge layer has a dopant concentration ranging from 0 to 10%.

14. The charge generation layer according to claim 13, wherein the P-type dopant in the first charge layer has a dopant concentration ranging from 2% to 20%; and/or the N-type dopant in the second charge layer has a dopant concentration ranging from 1% to 10%.

15. A stacked organic light-emitting device, comprising a first light-emitting device layer, a second light-emitting device layer, and a charge generation, comprising: a first charge layer and a second charge layer arranged in a stacked manner, one of the first charge layer and the second charge layer being doped with a P-type dopant and the other being doped with an N-type dopant, wherein in a direction from the first charge layer to the second charge layer, a dopant concentration in at least a portion of the first charge layer having an increasing trend, and a dopant concentration in at least a portion of the second charge layer having a decreasing trend, arranged in a stacked manner, wherein the first light-emitting device layer and the second light-emitting device layer are connected by means of the charge generation layer.
